(19) United States
(12) Patent Application Publication
(10) Pub. No.: US 2006/0011232 A1
(43) Pub. Date: Jan. 19, 2006

(54) Photoelectric transducer

(76) Inventors: Yusuke Suzuki, Kanagawa (JP); Masahiro Morooka, Kanagawa (JP); Kazuhiro Noda, Kanagawa (JP)

Correspondence Address: WOLF GREENFIELD & SACKS, PC;FEDERAL RESERVE PLAZA, 600 ATLANTIC AVENUE, BOSTON, MA, 02210-2211, US

(21) Appl. No.: 10/527,351

(22) PCT Filed: Aug. 22, 2003
(86) PCT No.: PCT/JP03/10653

§ 371 Date: Mar. 9, 2005

(30) Foreign Application Priority Data
Sep. 9, 2002 (JP) 2002-263159

(51) Int. Cl. H01L 31/00

(52) U.S. Cl. 136/256; 136/263

(57) ABSTRACT

The present invention relates to a photovoltaic element conveniently used for a solar cell. An ITO substrate coated with a metallic oxide or a derivative thereof is used as a transparent electrode (3). Thus, the fall of a resistance value is suppressed even when the photovoltaic element is exposed to high temperature or acid.

### TECHNICAL FIELD

The present invention relates to a photovoltaic element that exhibits excellent characteristics when it is used for a solar cell.

This application claims a priority based on Japanese Patent Application No. 2002-263159 filed on Sep. 9, 2002 which is incorporated in this application with reference thereto.

### BACKGROUND ART

As the solar cell, solar cells using a variety of materials with various qualities have been usually examined. Many solar cells using silicon have been sold at a market. The solar cell using silicon is roughly classified into a crystal silicon type solar cell using monocrystalline silicon or polycrystalline silicon and an amorphous silicon type solar cell. The monocrystalline or polycrystalline silicon has been usually substantially employed for the solar cell. In the crystal silicon type solar cell, conversion efficiency representing a performance for converting light (solar) energy to electric energy is higher than that of the amorphous silicon type solar cell. However, much energy and time are required to make the crystal grow, which results in a low productivity and a disadvantage in view of cost.

Further, the amorphous silicon type solar cell has the conversion efficiency lower than that of the crystal silicon type solar cell, however, has a light absorption property higher than that of the crystal silicon type solar cell. Accordingly, in the amorphous silicon type solar cell, a range for selecting a substrate is advantageously wide and an area is easily increased. The productivity of the amorphous silicon type solar cell is higher than that of the crystal silicon type solar cell, however, an energy burden has been yet high.

On the other hand, as a method for solving the above-described problems, solar cells using organic materials have been examined for a long time. However, most of them have the photovoltaic efficiency as low as about 1%, so that these solar cells have not been put to practical use. In the meantime, a dye-sensitized type solar cell published in Nature 353, 737, (1991) has hitherto disclosed that the photovoltaic efficiency as high as 10% can be realized and is considered to be capable of being produced at low cost. Accordingly, the dye-sensitized type solar cell has been paid attention to. A general structure of the dye-sensitized type solar cell is disclosed in Japanese Patent Application Laid-Open No. hei 1-220380 or the like.

A transparent electrode of the solar cell is preferably high in its transparency and electric conductivity, and ITO, SnO₂ and fluorine doped conductive glass (FTO) have been employed. Further, as a transparent electrode for the dye-sensitized type solar cell, the FTO has been widely used. The FTO is doped with fluorine to improve the heat resistance and acid resistance of a conductive film. However, as for the electric conductivity, no material that exceeds the ITO most widely employed as a transparent conductive thin film has been reported. The ITO can realize a very low resistance value as low as, for instance, 5 Ω/cm² or less and is inexpensive. Accordingly, when the solar cell can be formed by using the ITO, the solar cell having a higher performance can be inexpensively provided.

It has been known that when a conventional ITO is exposed to high temperature, its resistance value greatly rises and its high electric conductivity is lost by acid. In the dye-sensitized type solar cell, as disclosed in Gratzel et al. Nature 353 (2001) 737, since a process that acidic paste is sintered on a transparent electrode at from 400 to 500° C. is generally used, the ITO cannot be used as the transparent electrode of the dye-sensitized type solar cell.

### DISCLOSURE OF THE INVENTION

It is an object of the present invention to provide a new photovoltaic element that can solve the above-described problems of a conventional technique.

It is another object of the present invention to provide a photovoltaic element that uses as a transparent electrode an ITO whose resistance value is suppressed from being lowered when it is exposed to high temperature or acid.

A photovoltaic element according to the present invention includes an ITO substrate coated with a metallic oxide or a derivative thereof as a transparent electrode.

In the photovoltaic element according to the present invention, since the ITO substrate is coated with the metallic oxide or the derivative thereof, even when the photovoltaic element is exposed to high temperature in production processes, the rise of a resistance value of the ITO is prevented.

Still other objects of the present invention and specific advantages obtained by the present invention will be more apparent from an embodiment described by referring to the drawing.

### BRIEF DESCRIPTION OF THE DRAWING

FIG. 1 is a sectional view showing a photovoltaic element according to the present invention.

### BEST MODE FOR CARRYING OUT THE INVENTION

Now, a specific structure of a photovoltaic element according to the present invention will be described below.

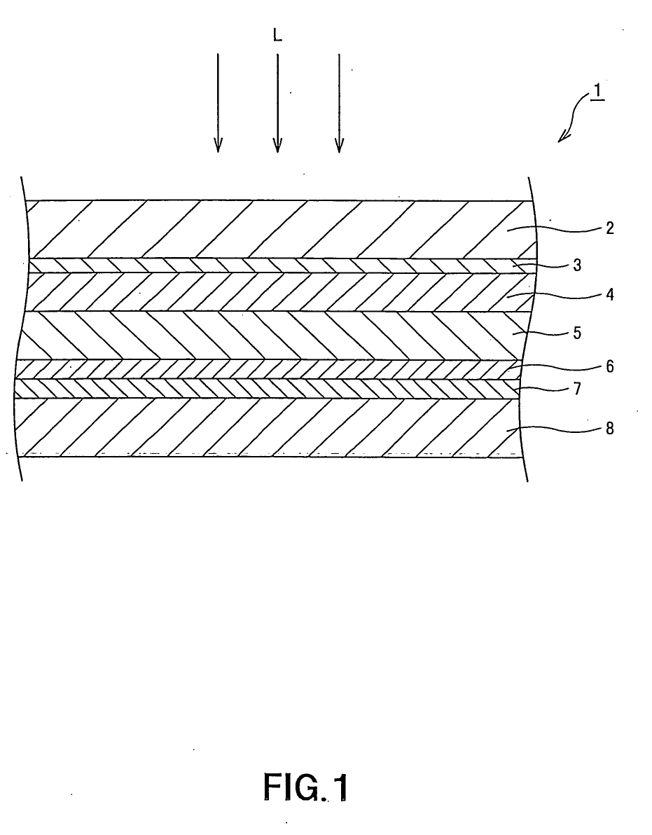

The photovoltaic element shown in FIG. 1 is a dye-sensitized type solar cell 1 and includes a transparent substrate 2, a transparent electrode 3, a metallic oxide semiconductor layer 4, an electrolyte layer 5, a counter electrode 6, an electrode 7 and a transparent substrate 8. The solar cell 1 is irradiated with light L from the transparent substrate 2 side.

The transparent substrates 2 and 8 are made of, for instance, a glass substrate, a transparent plastic substrate or the like.

The transparent electrode 3 is made of an ITO substrate. The ITO substrate may be formed with a single ITO film, a substrate doped with an element such as Zr, Hf, Te, F etc., or a laminated structure including other transparent conductive material. As the laminated structure, for instance, a structure that metal such as Au, Ag or Cu is laminated between ITO layers or a structure that a nitride layer is laminated between oxide layers are known, however, the laminated structure is not limited thereto.

Here, in the solar cell 1 according to the present invention, the surface of the ITO substrate as the transparent electrode located in the side in which the metallic oxide semiconductor layer 4 is formed is coated with a metallic oxide or a derivative thereof. The surface of the ITO substrate is coated with the metallic oxide, so that even when the solar cell 1 is exposed to high temperature or acid in its production processes, the rise of a resistance value of the ITO can be prevented. Thus, the ITO can be used as the transparent electrode and high photovoltaic characteristics can be realized.

As materials of a metallic oxide film, for instance, metallic oxides and derivatives thereof such as ZnO, NiO, SnO₂, Sb₂O₃, F doped ITO, etc. may be exemplified. The ITO substrate is coated with the metallic oxide films. Thus, the rise of the resistance value of the ITO can be suppressed without deteriorating the low resistance value of the ITO when the ITO substrate is exposed to the high temperature or the acid. As the characteristics of the metallic oxide used for coating, the metallic oxide for the dye-sensitized type solar cell needs to be stable up to about 500° C. depending on a range of temperature that requires a heat resistance.

The thickness of the metallic oxide film is determined depending on required heat resistance, transparency and electric conductivity, preferably not more than 500 nm and more preferably not more than 100 nm. A lower limit of the thickness of the film is set to about 10 nm. When the thickness of the film is not more than 10 nm, desired characteristics are hardly obtained.

The resistivity of the metallic oxide film is determined depending on a relation to the thickness of the film necessary for realizing the heat resistance, and preferably at least 5×10⁻³ Ω·cm or lower. When a resistance value is larger than 5×10⁻³ Ω·cm, the resistance value of the transparent electrode becomes high so that an adequate photovoltaic efficiency cannot be obtained.

The metallic oxide film preferably has the rise of the resistance value not higher than 10 Ω/cm² when the metallic oxide film is held for one hour in atmospheric air at 500° C. When the rise of the resistance value is larger than is 10 Ω/cm², the object of the present invention cannot be achieved.

The light transmittance of the ITO substrate coated with the metallic oxide film in from 400 nm to 900 nm is preferably at least 60% or higher. When the transmittance is lower than 60%, adequate photovoltaic characteristics cannot be obtained.

A method for forming the metallic oxide film is not especially limited to a specific method. Further, at least the surface of the ITO substrate located in the side in which the metallic oxide semiconductor layer 4 is formed may be coated with the metallic oxide film and an entire surface is not necessarily coated with the metallic oxide film.

The metallic oxide semiconductor layer 4 is formed in such a way that metallic oxide particles are sintered on the first transparent electrode 3. As materials of the metallic oxide semiconductor layer 4, for instance, metallic oxides such as TiO₂, MgO, ZnO, SnO₂, WO₃, Nb₂O₅, TiSrO₃ may be exemplified. The materials of the metallic oxide semiconductor layer 4 are not limited thereto and two or more kinds of metallic oxides may be mixed and the mixture may be used.

Further, on the metallic oxide semiconductor layer 4, a sensitizing dye is carried. The metallic oxide semiconductor is sensitized by the sensitizing dye.

As the sensitizing dye, any sensitizing dyes having a sensitizing action may be employed. For instance, bipyridine, phenanthroline derivative, xanthene dye, cyanine dye, basic dye, porphyrin compounds, azo dye, phthalocyanine compounds, anthraquinone dye, polycyclic quinone dye, etc. may be exemplified. Further, these sensitizing dyes may form complexes with metals such as ruthenium, zinc, platinum.

Semiconductor particles can be used as sensitizing materials as well as the above-described organic sensitizing dyes. As the semiconductor particles, semiconductor particles composed CdSe, CdTe, Pbs, InP, Si, etc. may be used. Further, as a sensitizer, two kinds or more of the above-described semiconductor particles may be combined together or the semiconductor particles may be combined with the organic dye.

In the electrolyte layer 5, at least one kind of material (an oxidation-reduction type) that reversibly generates a state change of oxidation-reduction is dissolved in electrolyte.

As solvents, nitrites such as acetonitrile, carbonates such as propylene carbonate, ethylene carbonate, other polar solvents such as pyridine, dimethyl acetoamide, room temperature molten salts such as methyl propyl imidazolium iodide or mixtures of them may be employed.

As examples of the oxidation-reduction type, for instance, halogens such as I-/I3-, Br/Br₂, pseudohalogens such as quinone/hydroquinone, SCN—/(SCN)₂, iron (II) ion/iron (III) ion, copper (I) ion/copper (II) ion, etc, may be exemplified, however, the examples are not limited thereto.

Further, a support electrolyte may be added to the electrolyte. As the support electrolyte, inorganic salts such as lithium iodide, sodium iodide or molten salts such as imidazolium, quaternary ammonium may be exemplified.

The electrolyte may be a liquid electrolyte, a gel electrolyte including the liquid electrolyte in a polymer material, a solid polymer electrolyte, or an inorganic solid electrolyte.

As the counter electrode 6, any of good conductors may be used. Metals such as platinum, platinum black, palladium, rhodium, ruthenium, etc. low in overvoltage relative to an oxidation-reduction reaction, carbons, conductive polymers, or compounds or mixtures of them may be exemplified as preferable materials.

The electrode 7 is a base material of the counter electrode 6. Ordinarily, glass, transparent conductive glass, metal, a polymer film, etc. are employed, however, the base material is not limited thereto. In this case, when there are pin holes in the counter electrode 6, desirably, the pin holes does not react with the electrolyte when the pin holes come into contact with the electrolyte. Further, in order to improve an adhesive property to a counter electrode layer, a layer made of Cr or the like may be provided.

In the dye-sensitized type solar cell 1 having the above-described structure, elements are respectively accommodated in a case and sealed or the elements and the case are entirely sealed by a resin. In this case, light is applied to the metallic oxide semiconductor layer 4 from the transparent substrate 2 side. Then, the solar cell 1 operates in such a manner as described below. That is, the light incident from the transparent substrate 2 side excites the dye carried on the surface of the metallic oxide semiconductor layer 4. The dye rapidly delivers electrons to the metallic oxide semiconductor layer 4. On the other hand, the dye that loses the electrons receives electrons from ions of the electrolyte layer 5 as a carrier moving layer. Molecules that deliver the electrons receive again electrons in the counter electrode 6. In such a way, electric current flows between both electrodes.

In the present invention, the surface of the ITO substrate serving as the transparent electrode is coated with the metallic oxide. Thus, even when the ITO substrate is exposed to high temperature or acid in the production processes, the rise of the resistance value of the ITO can be prevented. The solar cell 1 of the present invention that uses the ITO coated with the metallic oxide as the transparent electrode is excellent and has high photovoltaic characteristics.

In the above description, as the photovoltaic element, the dye-sensitized type solar cell is explained as an example. However, the present invention may be applied to a solar cell other than the dye-sensitized type solar cell or a photovoltaic element other than a solar cell. Further, a suitable change may be made as desired within a scope without departing the gist of the present invention.

### EXAMPLES

Now, examples carried out to recognize effects of the present invention are described below. However, the present invention is not limited to these examples.

### Example 1

TiO₂ paste was produced with reference to “Recent Advances in Research and Development for Dye-sensitized Solar Cells” (CMC).

Firstly, titanium isoproxide of 125 ml was agitated with 0.1 M nitric acid aqueous solution of 750 ml at room temperature and slowly dripped. When a dripping operation was finished, the solution was moved to a constant temperature bath at 80° C. and agitated for 8 hours so that opaque and translucent sol solution was obtained. The sol solution was cooled to the room temperature and was filtered by a glass filter. Then, the filtered sol solution of 700 ml was measured. The obtained sol solution was moved to an autoclave and hydrothermally processed for 12 hours at 220° C. Then, the sol solution was dispersed for one hour by an ultrasonic process. Then, the solution was concentrated by an evaporator at 40° C. and prepared so that the content of TiO₂ was 11 wt %. PEO having molecular weight of 500000 was added to the concentrated sol solution and the solution and PEO were uniformly mixed by a planetary ball mill to obtain TiO₂ paste whose viscosity was increased.

Further, an ITO substrate was coated with SnO₂. The ITO substrate coated with SnO₂ (5 Ω/cm²) was used as a transparent electrode. The obtained TiO₂ paste was applied on a glass ITO substrate coated with SnO₂ with a size of 0.7 cm×0.7 cm by a screen printing method, and then held for 120 minutes at 450° C. and to sinter TiO₂ on the ITO substrate coated with SnO₂ (5 Ω/cm²).

Then, the ITO substrate coated with SnO₂ on which TiO₂ was sintered was immersed for 12 hours in dehydrate ethanol solution in which cis-bis (isothiocyanate)-N,N-bis (2,2′-dipyridyl-4,4′-dicarboxylic acid)-ruthenium (II) dihydrate of 0.5 mM and deoxycholic acid of 20 mM were dissolved to adsorb a dye. This electrode was cleaned with ethanol solution of 4-tert-butylpyridine and dehydrate ethanol in order thereof and dried at a dark place.

As a counter electrode, a product obtained by sputtering platinum to the thickness of 100 nm on a fluorine doped conductive glass substrate (sheet resistance of 30 Ω/cm²) in which a liquid injection port of 1 mm was previously opened was used.

Further, lithium iodide (LiI) of 2 g, 1-propyl-2,3-dimethyl imidazolium iodide of 5 g, iodine (I₂) of 0.5 g, and 4-tert-butylpyridine of 2 g were dissolved in acetonitrile of 30.5 g to prepare electrolyte solution. This electrolyte solution was dripped on the semiconductor electrode and the semiconductor electrode was combined with the platinum sputtered counter electrode to produce a dye-sensitized solar cell.

### Example 2

An ITO substrate was coated with ZnO. The ITO substrate coated with ZnO (5 Ω/cm²) was used as a transparent electrode to produce a dye-sensitized solar cell in the same manner as that of the Example 1.

### Example 3

An ITO substrate was coated with WO₃. The ITO substrate coated with WO₃ (5 Ω/cm²) was used as a transparent electrode to produce a dye-sensitized solar cell in the same manner as that of the Example 1.

### Example 4

An ITO substrate was coated with Nb₂O₅. The ITO substrate coated with Nb₂O₅ (5 Ω/cm²) was used as a transparent electrode to produce a dye-sensitized solar cell in the same manner as that of the Example 1.

### Example 5

An ITO substrate was coated with Sb₂O₅. The ITO substrate coated with Sb₂O₅ (5 Ω/cm²) was used as a transparent electrode to produce a dye-sensitized solar cell in the same manner as that of the Example 1.

### Example 6

An ITO substrate was coated with CaGaO₄. The ITO substrate coated with CaGaO₄ (5 Ω/cm²) was used as a transparent electrode to produce a dye-sensitized solar cell in the same manner as that of the Example 1.

### Example 7

In this example, a dye-sensitized type solar cell was produced by using a gel electrolyte.

Lithium iodide (LiI) of 2 g, 1-propyl-2,3-dimethyl imidazolium iodide of 5 g, iodine (12) of 0.5 g, and 4-tert-butylpyridine of 2 g were dissolved in gamma butyrolactone of 30.5 g to prepare electrolyte solution. Dimethyl carbonate of 150 g was added to this electrolyte solution as a diluent. After the electrolyte solution was heated at 70° C., poly (vinylidene fluoride-hexafluoro propylene) copolymer of 8 g having molecular weight of 300000 was dissolved in the electrolyte solution to obtain sol type gel electrolyte precursor. Here, as the poly (vinylidene fluoride-hexafluoro propylene) copolymer, a product obtained under the copolymerization of vinylidene fluoride and hexafluoro propylene in the ratio of 96 to 4 was used.

Then, the sol type gel electrolyte precursor was applied on a semiconductor layer adsorbing a dye that was formed on an ITO coated with SnO₂ in the same manner as the Example 1 by a blade coating method and dried at 50° C. for 5 minutes to remove dimethyl carbonate and obtain a semiconductor electrode having gel electrolyte.

Finally, the semiconductor electrode with the gel electrolyte was combined with a counter electrode to form the dye-sensitized type solar cell.

### Example 8

An ITO substrate was coated with FTO. The ITO substrate coated with FTO (5 Ω/cm²) was used as a transparent electrode to produce a dye-sensitized solar cell in the same manner as that of the Example 1.

### Comparative Example 1

An ITO substrate (5 Ω/cm²) that was not coated with a metallic oxide was used as a transparent electrode to produce a dye-sensitized solar cell in the same manner as that of the Example 1.

### Comparative Example 2

An FFO substrate (15 Ω/cm²) that was not coated with a metallic oxide was used as a transparent electrode to produce a dye-sensitized solar cell in the same manner as that of the Example 1.

In each of the solar cells produced as described above, the resistance value of a transparent conductive substrate used as the transparent electrode, transmittance in from 400 to 900 nm, and the photovoltaic efficiency of the cell were measured and evaluated.

The resistance value of the transparent conductive substrate was measured after a film was formed and after the film was heated for one hour at 500° C. and gradually cooled to ambient temperature by using a low resistivity meter Loresta GP (trade name) produced by DIA Instruments Co., Ltd.

As for the photovoltaic efficiency, wide clips were respectively connected to a fluorine doped conductive glass substrate located in the transparent electrode side in each dye-sensitized solar cell and a platinum sputtered glass substrate located in the counter electrode side, and electric current generated by applying light to the dye-sensitized solar cell was measured by a current and voltage measuring device. A ratio of a maximum output to a light irradiation intensity obtained in this measurement was determined to be the photovoltaic efficiency. In applying light, a xenon lamp was used as a light source and light intensity on the dye-sensitized solar cell was set to 100 mW/cm².

Evaluated results are shown in Table 1.

TABLE 1

| | | | Surface Resistance | | |
|---|---|---|---|---|---|
| | | Trans- | (Ω) | | Photovoltaic |
| | Transparent | parency | Before | After | Efficiency |
| | Electrode | (%) | Heating | Heating | (%) |
| Example 1 | ITO/SnO₂ | 75 | 5.2 | 5.2 | 7.6 |
| Example 2 | ITO/ZnO | 73 | 5.1 | 5.2 | 7.1 |
| Example 3 | ITO/WO₃ | 71 | 5.1 | 5.3 | 7.3 |
| Example 4 | ITO/Nb₂O₅ | 71 | 5.2 | 5.3 | 7.1 |
| Example 5 | ITO/Sb₂O₅ | 74 | 5.1 | 5.1 | 7.7 |
| Example 6 | ITO/CaGaO₄ | 72 | 5.2 | 5.2 | 7.2 |
| Example 7 | ITO/SnO₂ | 75 | 5.2 | 5.2 | 6.9 |
| Example 8 | ITO/FTO | 81 | 5.1 | 5.1 | 7.6 |
| Comparative | ITO | 77 | 4.6 | 32.4 | 4.6 |
| Example 1 | | | | | |
| Comparative | FTO | 81 | 16.2 | 15.3 | 5.8 |
| Example 2 | | | | | |

As apparent from the Table 1, in the Comparative Example 1 in which the ITO substrate is not coated with the metallic oxide, a surface resistance after the film is heated is increased. Thus, an adequate photovoltaic efficiency is not obtained. Further, in the Comparative Example 2 in which the FTO substrate is used, the increase of resistance due to heating is low, however, an original resistance is higher than that of the ITO substrate, so that an adequate photovoltaic efficiency is not likewise obtained.

On the other hand, as apparent from the Examples 1 to 7 in which the metallic oxide film is formed on the ITO substrate, the increase of resistance after the film is heated is suppressed and the photovoltaic efficiency higher than that of the FTO is obtained.

As for the light transmittance of the transparent conductive substrate, the Comparative Example 1 is compared with the Examples 1 to 7. As a result, it is recognized that even when the metallic oxide film is formed, the light transmittance can be adequately maintained.

It is to be understood to a person with ordinary skill in the art that the present invention is not limited to the above-described embodiment and various changes, substitutions or equivalence thereto may be made without departing the scope of attached claims and the spirit thereof.

### INDUSTRIAL APPLICABILITY

In the photovoltaic element according to the present invention, the surface of the ITO substrate is coated with the metallic oxide so that the rise of the resistance value of the ITO substrate can be prevented even when the photovoltaic element is exposed to high temperature or acid in the production processes. In the present invention, the excellent photovoltaic element that can use the ITO substrate as the transparent electrode and has high photovoltaic characteristics can be inexpensively provided.

1. A photovoltaic element comprising an ITO substrate coated with a metallic oxide or a derivative thereof as a transparent electrode.

2. The photovoltaic element according to claim 1, wherein the metallic oxide includes at least one element among Ti, Cu, Zn, As, Sr, Nb, Ib, Sn and W.

3. The photovoltaic element according to claim 1, wherein when the metallic oxide film is held for one hour in atmospheric air at 500° C., the rise of a resistance value is 10 Ω/cm² or lower.

4. The photovoltaic element according to claim 1, wherein a light transmittance of the ITO substrate coated with the metallic oxide in from 400 nm to 900 nm is 60% or higher.

5. The photovoltaic element according to claim 1, further comprising a metallic oxide semiconductor carrying a dye: as an electrode of a dye-sensitized type solar cell.
